(19) United States
(12) Patent Application Publication
(10) Pub. No.: US 2025/0235977 A1
(43) Pub. Date: Jul. 24, 2025

(54) POLISHING HEAD WITH RETAINING RING WEAR SENSING

(71) Applicant: Applied Materials, Inc., Santa Clara, CA (US)

(72) Inventors: Jeonghoon Oh, Saratoga, CA (US); Andrew J. Nagengast, Sunnyvale, CA (US); Takashi Fujikawa, San Jose, CA (US); Kuen-Hsiang Chen, Sunnyvale, CA (US); Steven M. Zuniga, Soquel, CA (US)

(21) Appl. No.: 18/417,124

(22) Filed: Jan. 19, 2024

(51) Int. Cl. B24B 37/005; B24B 37/32; B24B 49/10; B24B 49/12

(52) U.S. Cl. CPC B24B 37/005; B24B 37/32; B24B 49/10; B24B 49/12

(57) ABSTRACT

A carrier head for chemical mechanical polishing includes a housing for attachment to a drive shaft. The housing includes an upper carrier body to be attached to a vertically stationary drive shaft and a lower carrier body that is vertically movable relative to the upper carrier body is configured to be secured to and suspend a retaining ring. A first flexible seal forms a loading chamber between the upper carrier body and the lower carrier body. A membrane assembly is arranged beneath the lower carrier body and includes a membrane support and a flexible membrane secured to the membrane support to form one or more lower pressurizable chambers. A second flexible seal forms an upper pressurizable chamber between the lower carrier body and the membrane support, and a sensor is secured to the housing and configured to measure a distance between the upper carrier body and the lower carrier body.

### TECHNICAL FIELD

This disclosure relates to a carrier head for use in chemical mechanical polishing (CMP) and to sensing the wear of a retaining ring.

### BACKGROUND

An integrated circuit is typically formed on a substrate by the sequential deposition of conductive, semiconductive, or insulative layers on a semiconductor wafer. A variety of fabrication processes require planarization of a layer on the substrate. For example, one fabrication step involves depositing a filler layer over a non-planar surface and planarizing the filler layer. For certain applications, the filler layer is planarized until the top surface of a patterned layer is exposed. For example, a metal layer can be deposited on a patterned insulative layer to fill the trenches and holes in the insulative layer. After planarization, the remaining portions of the metal in the trenches and holes of the patterned layer form vias, plugs, and lines to provide conductive paths between thin film circuits on the substrate. As another example, a dielectric layer can be deposited over a patterned conductive layer, and then planarized to enable subsequent photolithographic steps.

Chemical mechanical polishing (CMP) is one accepted method of planarization. This planarization method typically requires that the substrate be mounted on a carrier head. The exposed surface of the substrate is typically placed against a rotating polishing pad. The carrier head provides a controllable load on the substrate to push it against the polishing pad. A polishing slurry with abrasive particles is typically supplied to the surface of the polishing pad.

The substrate is typically retained below the carrier head by a retaining ring. Because the retaining ring is pressed against the polishing surface, the retaining ring also wears and eventually needs to be replaced.

### SUMMARY

In one aspect, a carrier head for chemical mechanical polishing includes a housing for attachment to a drive shaft. The housing includes an upper carrier body to be attached to a vertically stationary drive shaft and a lower carrier body that is vertically movable relative to the upper carrier body is configured to be secured to and suspend a retaining ring. A first flexible seal forms a loading chamber between the upper carrier body and the lower carrier body. A membrane assembly is arranged beneath the lower carrier body and includes a membrane support and a flexible membrane secured to the membrane support to form one or more lower pressurizable chambers. A second flexible seal forms an upper pressurizable chamber between the lower carrier body and the membrane support, and a sensor is secured to the housing and configured to measure a distance between the upper carrier body and the lower carrier body.

In another aspect, a chemical mechanical polishing system includes a platen, a motor having a vertically fixed drive shaft, a carrier head, a sensor, and a controller. The carrier head includes a retaining ring, a housing that has an upper carrier body attached to the drive shaft and a lower carrier body that is vertically movable relative to the upper carrier body is secured to and suspends the retaining ring, a first flexible seal forming a loading chamber between the upper carrier body and the lower carrier body, a membrane assembly that is arranged beneath the lower carrier body and that has a membrane support and a flexible membrane secured to the membrane support to form one or more lower pressurizable chambers, and a second flexible seal forming an upper pressurizable chamber between the lower carrier body and the membrane support. A sensor is secured to the housing and configured to measure a distance between the upper carrier body and the lower carrier body, and the controller is configured to receive a measurement from the sensor and, based on the measurement, at least one of i) determine whether the retaining ring should be replaced or ii) determine an adjustment for a pressure in the loading chamber or the upper pressurizable chamber.

Advantages of the foregoing may optionally include, but are not limited to, the following. The end-of-life of the retaining ring can be determined more precisely. Process control parameters can be adjusted to account for changes in the polishing-rate profile due to retaining ring wear, thus improving wafer-to-wafer uniformity.

The details of one or more implementations are set forth in the accompanying drawings and the description below. Other aspects, features, and advantages will be apparent from the description and drawings, and from the claims.

This invention relates to a carrier head for use in chemical mechanical polishing (CMP).

### BRIEF DESCRIPTION OF THE DRAWINGS

FIG. 1 is a schematic cross-sectional view of an example of a polishing apparatus.

FIG. 2 is a schematic cross-sectional view of a carrier head.

This invention relates to a carrier head for use in chemical mechanical polishing (CMP).

### DETAILED DESCRIPTION

A retaining ring is typically formed of a wearable plastic. Over the course of polishing of many substrates, e.g., one-hundred to five-hundred substrates, the retaining ring wears away and becomes thinner, and eventually needs to be replaced However, the wear rate and thus the exact time at which the retaining ring needs to be replaced can depend on the polishing process, and can vary from retaining ring to retaining ring. Thus it is desirable to have a technique to monitor the retaining ring thickness.

One approach to monitor the thickness of the plastic retaining ring is to use an eddy current sensor embedded in the platen to induce eddy currents in a metal backing ring. Two potential problems here are that this technique is generally subject to noise and that the approach may not function if the plastic portion is too thick or there is no metal backing ring. Another approach is to measure the vertical position of a load cup during loading. The load cup halts when it contacts the bottom surface of the retaining ring, and thus the displacement will depend on the retaining ring thickness. A potential problem here is that an external sensor is sensitive to environmental effects, e.g., presence of water or slurry in the load cup, which can interfere with the measurement, and a sensor integrated into the actuator itself may not be reliable.

A potential solution is to cause the carrier head to press the substrate against the polishing pad, and then to use an internal sensor to measure the distance between the vertically stationary piece secured to the drive shaft, and the carrier body that holds the retaining ring.

In some polishing systems, a membrane in a carrier head is used to apply pressure on a substrate during polishing. For example, a chamber above a membrane assembly can be pressurized to urge the membrane against the substrate. However, as a retaining ring of the carrier head wears, the load on the substrate can increase, resulting in wafer-to-wafer non-uniformity. For example, as the retaining ring wears, the deflection of a flexure connecting the membrane assembly to the carrier head can increase, resulting in greater down force on the membrane assembly, which in turn can increase the loading on the flexible membrane and the substrate. A potential solution is to adjust a chamber pressure applied to the membrane assembly to compensate for any change in the down force from the flexure so that the total loading on the substrate stays relatively constant. A measurement of the distance between the housing, and the carrier body that holds the retaining ring can be used as the basis to select and adjustment to the chamber pressure.

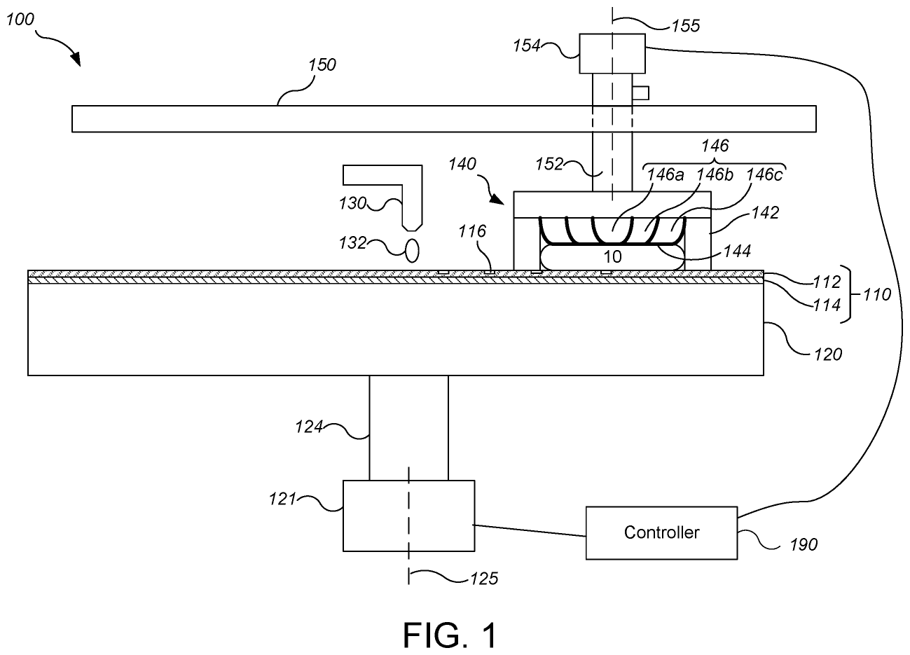

FIG. 1 illustrates an example of a chemical mechanical polishing apparatus 100. The polishing apparatus 100 includes a rotatable disk-shaped platen 120 on which a polishing pad 110 is situated. The platen is operable to rotate about an axis 125. For example, a motor 121, e.g., a DC induction motor, can turn a drive shaft 124 to rotate the platen 120.

The polishing pad 110 can be a two-layer polishing pad with an outer polishing layer 112 and a softer backing layer 114. In some implementations, a plurality of slurry-transport grooves 116 are formed in the top surface of the polishing layer 112 of the polishing pad 110.

The polishing apparatus 100 can include a port 130 to dispense a polishing liquid 132, such as an abrasive slurry, onto the polishing pad 110. The polishing apparatus can also include a polishing pad conditioner to abrade the polishing pad 110 to maintain the polishing pad 110 in a consistent abrasive state.

The polishing apparatus 100 includes at least one carrier head 140. The carrier head 140 is operable to hold a substrate 10 against the polishing pad 110 with a controllable pressure, such as during a polishing process.

The carrier head 140 can include a retaining ring 142 to retain the substrate 10 below a flexible membrane 144. The carrier head 140 also includes one or more independently controllable pressurizable chambers 146 defined by the membrane, e.g., three chambers 146a-146c, which can apply independently controllable pressurizes to associated zones on the flexible membrane 144 and thus on the substrate 10. Although only three chambers 146a-146c are illustrated in FIG. 1 for ease of illustration, there could be one or two chambers, or four or more chambers, e.g., five chambers.

The carrier head 140 is suspended from a support structure 150, e.g., a carousel or track, and is connected by a drive shaft 152 to a carrier head rotation motor 154, e.g., a DC induction motor, so that the carrier head can rotate about an axis 155. Optionally each carrier head 140 can oscillate laterally, e.g., on sliders on the support structure 150, or by rotational oscillation of the carousel itself, or by sliding along the track. In typical operation, the platen is rotated about its central axis 125, and each carrier head is rotated about its central axis 155 and translated laterally across the top surface of the polishing pad.

A controller 190, such as a programmable computer, is connected to the motors 121, 154 to control the rotation rate of the platen 120 and carrier head 140.

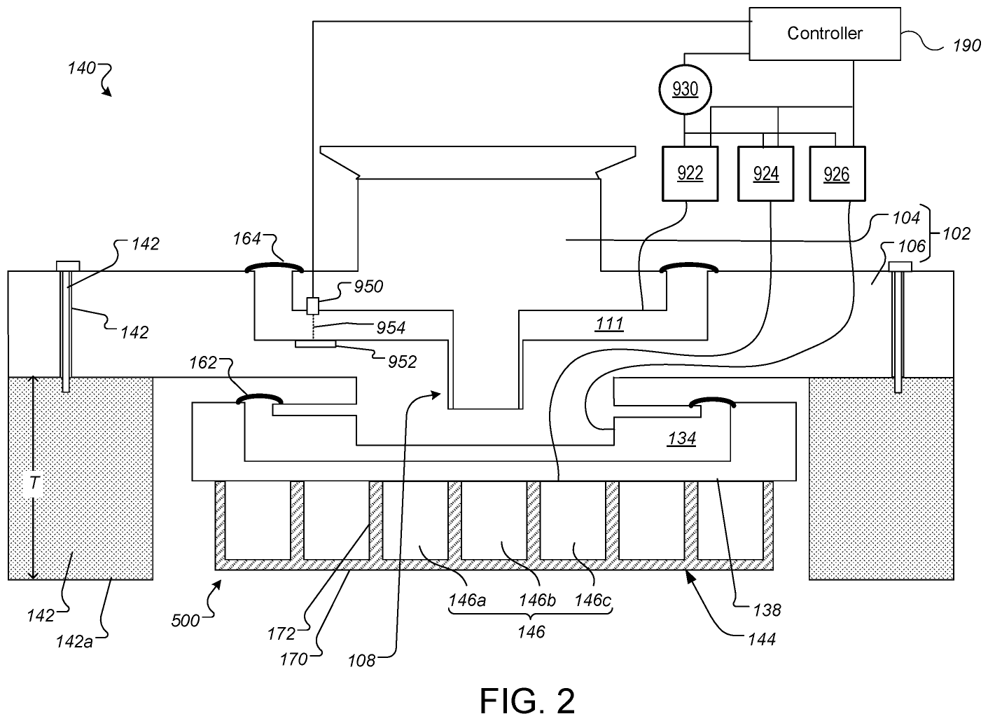

Referring to FIG. 2, the carrier head 140 includes a housing 102 with an upper carrier body 104 and a lower carrier body 106, a gimbal mechanism 108 (which may be considered part of the lower carrier body 106), a retaining ring 142 connected to the lower carrier body 106, and a membrane assembly 500.

A volume between lower carrier body 106 and the upper carrier body 104 can be sealed by an upper flexible seal 164 to provide a loading chamber 111. This upper flexible seal 164 can flex to accommodate the change in vertical position between the upper carrier body 104 and the lower carrier body 106.

The upper carrier body 104 is secured to the drive shaft 152 to rotate the entire carrier head 140. The upper carrier body 104 can generally be circular in shape. There may be passages extending through the upper carrier body 104 for pneumatic control of the carrier head 140. The lower carrier body 106 is located beneath the upper carrier body 104, and is vertically movable relative to the upper carrier body 104. The loading chamber 111 is located between the upper carrier body 104 and the lower carrier body 106 to apply a load, i.e., a downward pressure or weight, to the lower carrier body 106. The vertical position of the lower carrier body 106 relative to a polishing pad is also controlled by the loading chamber 111. In some embodiments, the vertical position of the lower carrier body 106 relative to the polishing pad is controlled by an actuator.

The gimbal mechanism 108 permits the lower carrier body 106 to gimbal and vertically move relative to the upper carrier body 104 while preventing lateral motion of the lower carrier body 106 relative to the upper carrier body 104. However, in some implementations, there is no gimbal.

The substrate 10 is held beneath the carrier head 140 by the retaining ring 142 which retains the substrate 10 against lateral motion. The retaining ring 142 can also provide active edge process control; control of pressure on the polishing pad in a region outside the substrate but adjacent the substrate edge can effect polishing rates at the substrate edge. Some implementations can include an outer ring which can provide positioning or referencing of the carrier head to the surface of the polishing pad.

A volume between the lower carrier body 106 and the membrane assembly 500 can be sealed by a lower flexible seal 162 to form an upper pressurizable chamber 134. This lower flexible seal 162 can flex to accommodate the change in vertical position between the lower carrier body 106 and the membrane assembly 500. Pressure in the upper pressurizable chamber can control the downward load on the membrane assembly 500 and/or the vertical position of the membrane assembly 500 relative to the housing

The membrane assembly 500 can include a membrane support 138 and the flexible membrane 144. The membrane support 138 can be formed of a material that is more rigid than the membrane 144, e.g., a metal, ceramic, or hard plastic. The flexible membrane 144 has a circular lower portion 170 having a lower outer surface that provides a mounting surface for the substrate. The flexible membrane 144 also has a plurality of flaps 172, e.g., annular flaps, that extend from the inner surface of the membrane to define the individually controllable pressurizable chambers 146. For example, the ends of the flaps 172 can be clamped to the membrane support 138.

In some implementations, the flexible membrane 144 is directly secured to the lower carrier body 106. In this case, the lower carrier body 106 serves as the membrane support and there is no upper pressurizable chamber.

Each chamber in the carrier head 140 can be fluidly coupled by passages through the upper carrier body 104 and the lower carrier body 106 to an associated pressure source (e.g., a pressure source 922, 924, 926), such as a pump or pressure or vacuum line. There can be one or more passages for the loading chamber 111, for the upper pressurizable chamber 134, for each of the lower upper pressurizable chamber 146. One or more passages from the lower carrier body 106 can be linked to passages in the upper carrier body 104 by flexible tubing that extends inside the loading chamber 111 or outside the carrier head 140. Pressurization of each chamber can be independently controlled. In particular, pressurization of each chamber 146 can be independently controlled. This permits different pressures to be applied to different radial regions of the substrate 10 during polishing, thereby compensating for non-uniform polishing rates.

The controller 190 regulates the pressure of the various chambers of the carrier head 140. The controller 190 is coupled to a plurality of pressure sources, e.g., pressure source 922, pressure source 924, and pressure source 926. The pressure sources 922, 924, 926 can be, for example, a pump, a facilities gas line and controllable valve, etc. Each of the pressure sources 922, 924, 926 can be individually connected to a pressurizable chamber.

A sensor 930 measures the pressure(s) in the pressure sources 922, 924, 926, the individually pressurizable lower chambers 146, the pressurizable upper chamber 134, and the loading chamber 111. The sensor 930 communicates the measured pressure(s) to the controller 190. The controller 190 causes the pressure sources 922, 924, 926 to increase and/or decrease the pressure in loading chamber 111, the pressurizable lower chambers 146, and/or the pressurizable upper chamber 134.

As the carrier head 140 performs polishing operations, the retaining ring 142 wears away, and the total thickness T of the retaining ring decreases.

To monitor the thickness of the retaining ring 142, a sensor 950 can measure the distance or a change in distance from the upper carrier body 104 to the lower carrier body 106. The sensor 950 can be secured to the upper carrier body 104, e.g., secured in a recess in or attached to a bottom surface of the upper carrier body 104. The sensor 950 is positioned to measure a distance between the sensor 950 and a target 952. For example, the target 952 can be a portion of the top surface of the lower carrier body 106. Alternatively, the sensor 950 can be secured to the lower carrier body 106, e.g., secured in a recess in or attached to the top surface of lower carrier body 106, and the target 952 can be a portion of the bottom surface of the upper carrier body 104.

The sensor 950 can be a non-contact sensor, such as an inductively coupled sensor, a capacitively coupled sensor, or a laser displacement sensor that directs a light beam 954 to the target. The target 952 can be adapted to enhance the sensor 950, e.g., be a conductive region for an inductively coupled sensor or a reflective surface for a laser displacement sensor.

Alternatively, the sensor 950 can be a contact sensor, a linear variable differential transformer (LVDT). Contact sensors are typically more sensitive and vulnerable to environmental conditions, but because the sensor 950 is inside an environmentally protected area inside the carrier head 140, this option is feasible.

In operation, the chamber 111 is pressurized to push the lower carrier body 106 and retaining ring 142 downward until the bottom surface 142a of the retaining ring 142 contacts the polishing pad 110. When the retaining ring 142 is in contact with the pad, the distance between the sensor 950 and target 952 is measured. Because the drive shaft 152 and upper carrier body 104 are in a fixed vertical position, this can ensure a consistent measurement of the distance between the upper carrier body 104 and the lower carrier body 106.

Further, the sensor 950 is connected to the controller 190, and reports the measured distance or change in measured distance (e.g., a decreased distance due to wear of the retaining ring 142) to the controller 190.

The measured distance can be subtracted from a predetermined starting thickness, e.g., the thickness of the retaining ring 142 before attachment to the carrier head for use in polishing, to provide a current thickness of the retaining ring. If the thickness of the retaining ring 142 falls below a minimum retaining ring thickness value, then the controller 190 can generate an alert indicating that the retaining ring 142 needs to be replaced. Alternatively, if the measured distance exceeds a maximum change in thickness value, then the controller 190 can generate an alert indicating that the retaining ring 142 needs to be replaced.

The controller 190 can also be configured to cause the pressure source 922 to adjust the pressure in the loading chamber 111, cause the pressure source 926 to adjust the pressure in the upper pressurizable chamber 134, or both, to maintain the load on the substrate 10 and retaining ring 142. In particular, the controller 190 can be configured to reduce the pressure in the upper pressurizable chamber 134 as the retaining ring wears and becomes thinner. For example, the controller 190 can include a look-up table that provides a pressure or pressure offset for the upper pressurizable chamber 134 as a function of the retaining ring thickness. A pressure offset can be subtracted from a desired pressure calculated by some other algorithm, e.g., a desired pressure calculated for control of the polishing rate.

The controller and other computing devices part of systems described herein can be implemented in digital electronic circuitry, or in computer software, firmware, or hardware. For example, the controller can include a processor to execute a computer program as stored in a computer program product, e.g., in a non-transitory machine readable storage medium. Such a computer program (also known as a program, software, software application, or code) can be written in any form of programming language, including compiled or interpreted languages, and it can be deployed in any form, including as a standalone program or as a module, component, subroutine, or other unit suitable for use in a computing environment.

In context of the controller, “configured” indicates that the controller has the necessary hardware, firmware or software or combination to perform the desired function when in operation (as opposed to simply being programmable to perform the desire function).

While this document contains many specific implementation details, these should not be construed as limitations on the scope of any inventions or of what may be claimed, but rather as descriptions of features specific to particular embodiments of particular inventions. Certain features that are described in this document in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

A number of embodiments of the invention have been described. Nevertheless, it will be understood that various modifications may be made without departing from the spirit and scope of the invention. Accordingly, other implementations are within the scope of the following claims.

What is claimed is:

1. A carrier head for chemical mechanical polishing, comprising:
a housing for attachment to a drive shaft, wherein the housing includes an upper carrier body to be attached to a vertically stationary drive shaft and a lower carrier body that is vertically movable relative to the upper carrier body is configured to be secured to and suspend a retaining ring;
a first flexible seal forming a loading chamber between the upper carrier body and the lower carrier body;
a membrane assembly arranged beneath the lower carrier body, the membrane assembly comprising a membrane support and a flexible membrane secured to the membrane support to form one or more lower pressurizable chambers;
a second flexible seal forming an upper pressurizable chamber between the lower carrier body and the membrane support; and
a sensor secured to the housing and configured to measure a distance between the upper carrier body and the lower carrier body.

2. The carrier head of claim 1, wherein the sensor is secured to the upper carrier body and is configured to sense a distance between the sensor and a target on the lower carrier body.

3. The carrier head of claim 2, wherein the target is a top surface of the lower carrier body.

4. The carrier head of claim 3, wherein sensor is an optical sensor and the target is reflective.

5. The carrier head of claim 1, wherein the sensor is secured to the lower carrier body and is configured to sense a distance between the sensor and a target on the upper carrier body.

6. The carrier head of claim 5, wherein the target is a bottom surface of the upper carrier body.

7. The carrier head of claim 6, wherein the sensor is an optical sensor and the target is reflective.

8. The carrier head of claim 1, wherein the sensor is a non-contact sensor.

9. The carrier head of claim 8, wherein the sensor is an inductively coupled sensor or a capacitively coupled sensor.

10. The carrier head of claim 1, wherein the sensor is a laser displacement sensor.

11. The carrier head of claim 1, wherein the sensor is a contact sensor.

12. The carrier head of claim 11, wherein the sensor is a linear variable differential transformer (LVDT).

13. A chemical mechanical polishing system, comprising:
a platen;
a motor having a vertically fixed drive shaft;
a carrier head including
a retaining ring,
a housing that includes an upper carrier body attached to the drive shaft and a lower carrier body that is vertically movable relative to the upper carrier body is secured to and suspends the retaining ring,
a first flexible seal forming a loading chamber between the upper carrier body and the lower carrier body,
a membrane assembly arranged beneath the lower carrier body, the membrane assembly comprising a membrane support and a flexible membrane secured to the membrane support to form one or more lower pressurizable chambers,
a second flexible seal forming an upper pressurizable chamber between the lower carrier body and the membrane support, and
a sensor secured to the housing and configured to measure a distance between the upper carrier body and the lower carrier body; and
a controller configured to receive a measurement from the sensor and, based on the measurement, at least one of i) determine whether the retaining ring should be replaced or ii) determine an adjustment for a pressure in the loading chamber or the upper pressurizable chamber.

14. The system of claim 13, wherein the controller is configured to determine a retaining ring thickness from the measurement from the sensor, and to determine whether the retaining ring thickness falls below a threshold value, and to generate an alert if the retaining ring thickness is determined to fall below the threshold value.

15. The system of claim 13, wherein the controller is configured to determine whether the measured distance exceeds a threshold value, and to generate an alert if the measured distance is determined to exceed the threshold value.

16. The system of claim 13, wherein the sensor is secured to the upper carrier body and is configured to sense a distance between the sensor and a target on the lower carrier body.

17. The system of claim 13, wherein the sensor is secured to the lower carrier body and is configured to sense a distance between the sensor and a target on the upper carrier body.

18. The system of claim 13, wherein the sensor is an inductively coupled sensor, a capacitively coupled sensor, or a laser displacement sensor.

19. The system of claim 13, wherein the sensor is a linear variable differential transformer (LVDT).

20. The system of claim 13, wherein the controller is configured to determine an adjustment for a pressure in the loading chamber or the upper pressurizable chamber to compensating for changes in load on the membrane assembly based on wear of the retaining ring.
